(19) United States
(12) Patent Application Publication
(10) Pub. No.: US 2025/0270692 A1
(43) Pub. Date: Aug. 28, 2025

(54) SUBSTRATE PROCESSING APPARATUS

(71) Applicant: TOKYO ELECTRON LIMITED, Tokyo (JP)

(72) Inventors: Masato KADOBE, Tokyo (JP); Mitsuru YAMAZAKI, Iwate (JP)

(21) Appl. No.: 19/054,543

(22) Filed: Feb. 14, 2025

(30) Foreign Application Priority Data
Feb. 22, 2024 (JP) 2024-025083

(51) Int. Cl. C23C 16/455; C23C 16/44; C23C 16/46

(52) U.S. Cl. CPC C23C 16/455; C23C 16/4412; C23C 16/46

(57) ABSTRACT

A substrate processing apparatus, includes: a reaction tube; a gas introducer configured to introduce gas to an interior of the reaction tube; a gas exhauster configured to exhaust the gas introduced to the interior of the reaction tube; a first heater configured to heat the reaction tube; a second heater configured to heat the gas exhauster; and a housing configured to accommodate the reaction tube, the gas introducer, the gas exhauster, the first heater, and the second heater in an interior of the housing.

### CROSS-REFERENCE TO RELATED APPLICATION

This application is based upon and claims the benefit of priority from Japanese Patent Application No. 2024-025083, filed on Feb. 22, 2024, the entire contents of which are incorporated herein by reference.

### TECHNICAL FIELD

The present disclosure relates to a substrate processing apparatus.

### BACKGROUND

A batch-type substrate processing apparatus that collectively processes a plurality of substrates is known (see, for example, Patent Documents 1 and 2). In the substrate processing apparatus disclosed in Patent Document 1, an exhaust pipe is installed below a reaction tube, and a heater terminal is provided in a vertical side or a side surface of a heat reflector. In the substrate processing apparatus disclosed in Patent Document 2, a gas introduction pipe and a gas exhaust pipe are provided at opposing positions on a side surface of a reaction tube.

### Prior Art Documents

### Patent Documents

Patent Document 1: Japanese Patent Laid-Open Publication No. 2001-210631

Patent Document 2: Japanese Patent Laid-Open Publication No. 2008-172205

### SUMMARY

According to one embodiment of the present disclosure, there is provided a substrate processing apparatus, includes: a reaction tube; a gas introducer configured to introduce gas to an interior of the reaction tube; a gas exhauster configured to exhaust the gas introduced to the interior of the reaction tube; a first heater configured to heat the reaction tube; a second heater configured to heat the gas exhauster; and a housing configured to accommodate the reaction tube, the gas introducer, the gas exhauster, the first heater, and the second heater in an interior of the housing.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a perspective view 1 showing a substrate processing apparatus according to an embodiment.

FIG. 2 is a perspective view 2 showing the substrate processing apparatus according to the embodiment.

FIG. 3 is a vertical cross-sectional view showing the substrate processing apparatus according to the embodiment.

FIG. 4 is a horizontal cross-sectional view 1 showing the substrate processing apparatus according to the embodiment.

FIG. 5 is a horizontal cross-sectional view 2 showing the substrate processing apparatus according to the embodiment.

FIG. 6 is a view 1 showing an arrangement of side heaters.

FIG. 7 is a view 2 showing the arrangement of the side heaters.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limitative exemplary embodiments of the present disclosure will be described with reference to the accompanying drawings. Throughout all the accompanying drawings, the same or corresponding members or components will be denoted by the same or corresponding reference numerals, and redundant descriptions thereof will be omitted.

### Substrate Processing Apparatus

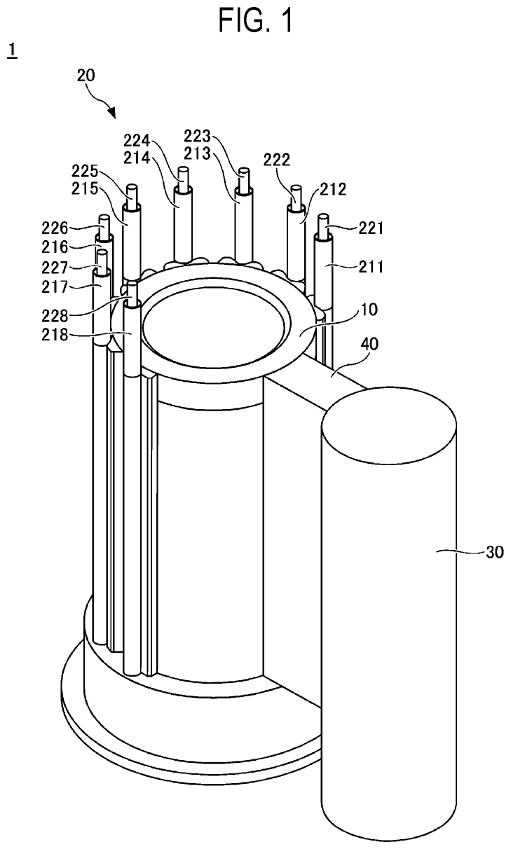

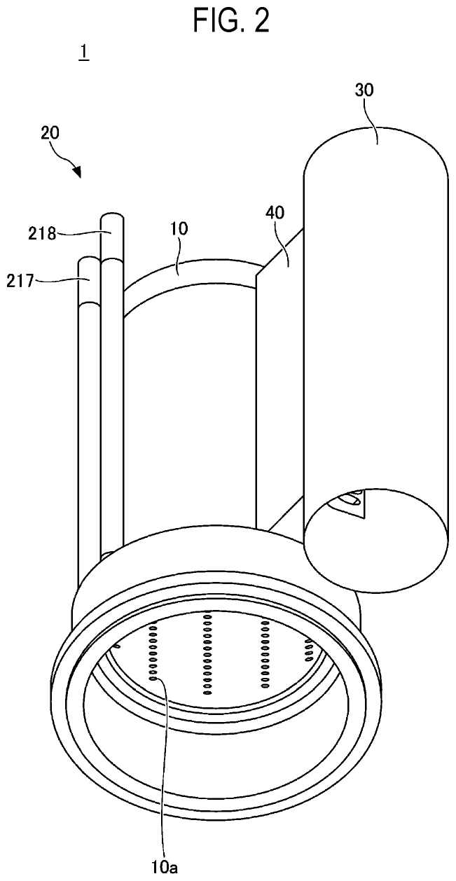

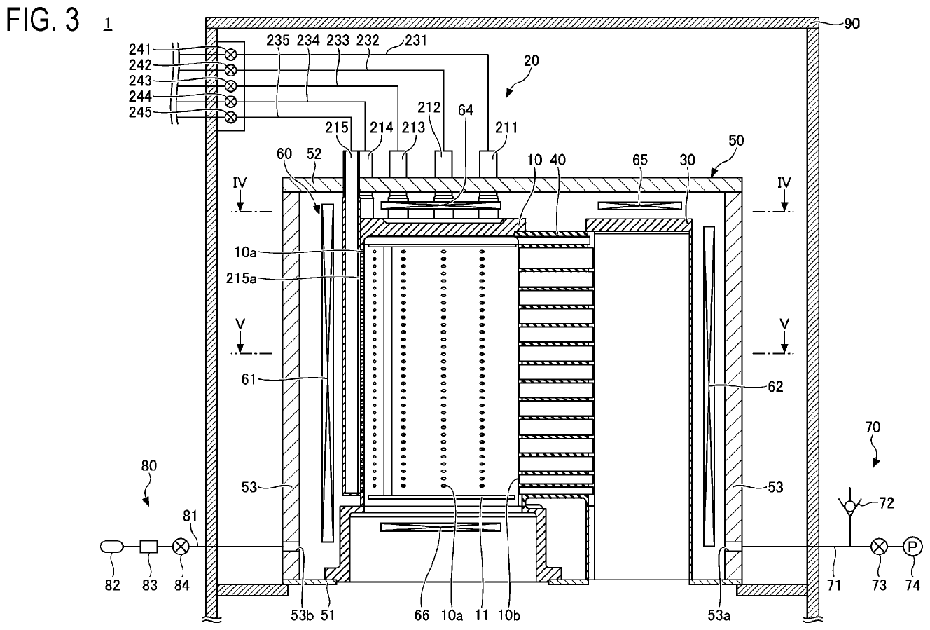

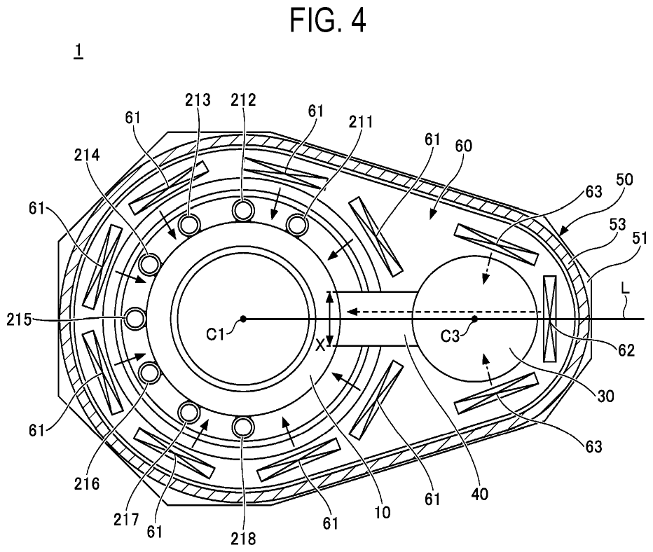

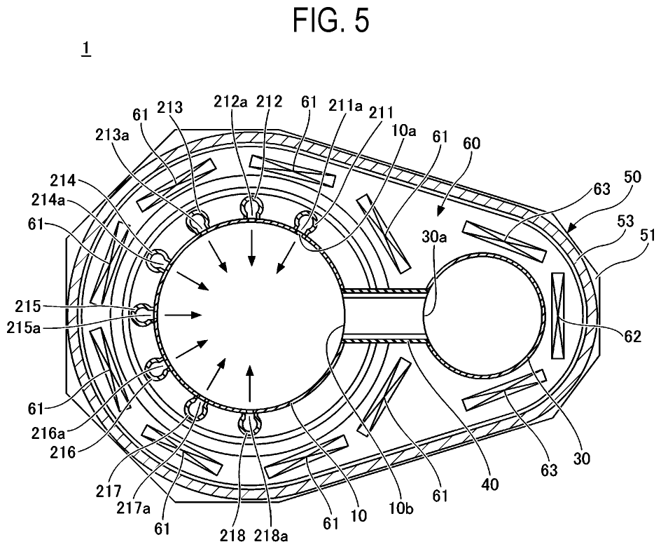

A substrate processing apparatus 1 according to an embodiment is described with reference to FIGS. 1 to 5. FIG. 1 is a perspective view showing the substrate processing apparatus 1 according to the embodiment when the substrate processing apparatus 1 is viewed obliquely from above. FIG. 2 is a perspective view showing the substrate processing apparatus 1 according to the embodiment when the substrate processing apparatus 1 is viewed obliquely from below. FIG. 3 is a vertical cross-sectional view showing the substrate processing apparatus 1 according to the embodiment. FIG. 4 is a horizontal cross-sectional view showing the substrate processing apparatus 1 according to the embodiment, taken along line IV-IV in FIG. 3 in an arrow direction. FIG. 5 is a horizontal cross-sectional view showing the substrate processing apparatus 1 according to the embodiment, taken along line V-V in FIG. 3 in an arrow direction.

The substrate processing apparatus 1 is a batch-type apparatus that collectively performs various processes on a plurality of substrates. The various processes include, for example, a film formation process for forming films on the substrates by atomic layer deposition (ALD) or chemical vapor deposition (CVD). The various processes may include an etching process for removing the films formed on the substrates.

The substrate processing apparatus 1 includes a reaction tube 10, a gas introducer 20, a vacuum pipe 30, an exhaust duct 40, a housing 50, a heating part 60, a depressurizer 70, a pressurizer 80, and an apparatus housing 90. In FIGS. 1 and 2, the housing 50, the heating part 60, the depressurizer 70, the pressurizer 80, and the apparatus housing 90 are not illustrated. The reaction tube 10, the gas introducer 20, and the exhaust duct 40 are joined together by, for example, welding, and are integrally formed. The reaction tube 10, the vacuum pipe 30, and exhaust duct 40 are formed of, for example, quartz.

The reaction tube 10 has a cylindrical shape with an open lower end and a ceiling. An introduction opening 10a and an exhaust opening 10b are formed in an outer wall of the reaction tube 10.

The introduction opening 10a penetrates the outer wall of the reaction tube 10. The introduction opening 10a is formed at positions at which gas introduction ducts 211 to 218, which will be described later, are installed along a circumferential direction of the reaction tube 10. A plurality of introduction openings 10a is formed along a vertical direction from a vicinity of an upper end to a vicinity of a lower end of the reaction tube 10 at each position along the circumferential direction of the reaction tube 10. In this case, it is easy to uniformly supply gas to a range from the upper end to the lower end of the reaction tube 10.

The exhaust opening 10b penetrates the outer wall of the reaction tube 10. The exhaust opening 10b is formed at a position different from the position of the introduction opening 10a in the circumferential direction of the reaction tube 10. The exhaust opening 10b is formed at a position at which the exhaust duct 40 is installed in the circumferential direction of the reaction tube 10. The exhaust opening 10b is a rectangular opening that extends in the vertical direction from the vicinity of the upper end to the vicinity of the lower end of the reaction tube 10. In this case, it is easy to uniformly exhaust gas over a range from the upper end to the lower end of the reaction tube 10.

A lower end opening of the reaction tube 10 is hermetically sealed by a cover (not shown). The cover is made of, for example, metal such as stainless steel. A substrate holder 11 (FIG. 3) is accommodated inside the reaction tube 10. The substrate holder 11 holds a plurality of substrates in a horizontal posture arranged in multiple stages in the vertical direction. The number of substrates is not limited, but is, for example, between 25 and 200. The substrate holder 11 is made of, for example, quartz.

The gas introducer 20 includes gas introduction ducts 211 to 218, nozzles 221 to 228, gas introduction pipes 231 to 238, and opening/closing valves 241 to 248. In FIG. 3, the gas introduction pipes 231 to 235 and the opening/closing valves 241 to 245 are shown.

The gas introduction ducts 211 to 218 are installed along the circumferential direction of the reaction tube 10. The gas introduction ducts 211 to 218 are installed to be spaced apart from each other in the circumferential direction of the reaction tube 10. Thereby, the adjacent gas introduction ducts 211 to 218 may have a reduced thermal effect on each other. Therefore, it is possible to suppress a temperature drop within the gas introduction ducts 211 to 218 and suppress the generation of particles. The gas introduction ducts 211 to 218 are radially installed at intervals in the circumferential direction of the reaction tube 10. In this case, as indicated by arrows in FIG. 5, gases such as a raw material gas, a reaction gas, an etching gas, and a purge gas may be supplied to the inside of the reaction tube 10 from a plurality of positions (in multiple directions) in the circumferential direction of the reaction tube 10. Thereby, an in-plane shape of a film formation or etching process may be easily adjusted. For example, a retention time of gas supplied to surfaces of the substrates or a gas concentration distribution may be adjusted by adjusting a gas supply position or the amount of gas supplied. Therefore, it is easy to control the in-plane shape of the film formation or etching process compared to a unidirectional gas flow. The gas introduction ducts 211 to 218 may be installed, for example, in this order counterclockwise from the exhaust opening 10b.

The gas introduction ducts 211 to 218 are installed on the outer wall of the reaction tube 10. In this case, a distance from the gas introduction ducts 211 to 218 to the substrates is shortened. Therefore, unnecessary thermal decomposition of the gas may be suppressed. In addition, when the gas introduction ducts 211 to 218 are installed on the outer wall of the reaction tube 10, there is no need to dispose the nozzles 221 to 228 inside the reaction tube 10. For this reason, a space between outer edges of the substrates and an inner wall of the reaction tube 10 may be narrowed, thereby suppressing a gas flow into the space. As a result, the efficiency of gas supply between the vertically adjacent substrates is improved. Additionally, when the gas introduction ducts 211 to 218 are installed on the outer wall of the reaction tube 10, there is no need to form a nozzle chamber for accommodating the nozzles 221 to 228 by protruding a side wall of the reaction tube 10 radially outward. The gas introduction ducts 211 to 218 are integrally formed with, for example, the reaction tube 10. The gas introduction ducts 211 to 218 are formed of, for example, quartz.

The gas introduction ducts 211 to 218 have a tubular shape with a closed lower end and an open upper end. The upper ends of the gas introduction ducts 211 to 218 extend upward from an upper surface of the reaction tube 10 and penetrate the housing 50. In this case, an upper space of the housing 50 may be used as a space for installing the gas introduction pipes 231 to 238 or the opening/closing valves 241 to 248. Therefore, a pipe distance from the opening/closing valves 241 to 248 to the reaction tube 10 may be shortened. Further, the shape of the gas introduction pipes 231 to 238 may be simplified. Gas holes 211a to 218a (FIG. 5) are formed at positions of the gas introduction ducts 211 to 218 facing the reaction tube 10.

Each of the gas holes 211a to 218a has a rectangular shape extending in the vertical direction from the vicinity of the upper end to the vicinity of the lower end of the reaction tube 10. For example, each of the gas holes 211a to 218a extends from above the uppermost introduction opening 10a to below the lowermost introduction opening 10a. Gas flowing inside the gas introduction ducts 211 to 218 is discharged into the reaction tube 10 from the gas holes 211a to 218a.

The gas introduction duct 211 is installed in an angle range less than 90 degrees counterclockwise from the exhaust duct 40 in the circumferential direction of the reaction tube 10. The gas introduction duct 212 is installed at an angle of 90 degrees counterclockwise from the exhaust duct 40 in the circumferential direction of the reaction tube 10. The gas introduction ducts 213 and 214 are installed at an angle range greater than 90 degrees and less than 180 degrees counterclockwise from the exhaust duct 40. The gas introduction duct 215 is installed at an angle of 180 degrees counterclockwise from the exhaust duct 40 in the circumferential direction of the reaction tube 10. In other words, the gas introduction duct 215 is installed at a position opposite to the exhaust duct 40. The gas introduction ducts 216 and 217 are installed at an angle range greater than 180 degrees and less than 270 degrees counterclockwise from the exhaust duct 40. The gas introduction duct 218 is installed at an angle of 270 degrees counterclockwise from the exhaust duct 40. In other words, the gas introduction duct 218 is installed at a position opposite to the gas introduction duct 212.

The nozzles 221 to 228 are detachably inserted into the interior of the gas introduction ducts 211 to 218. In this case, the shape of the nozzles 221 to 228 may be changed according to the type of process, so that the optimal nozzles 221 to 228 may be used according to the type of process. An inner surface of each of the gas introduction ducts 211 to 218 has a shape according to an outer surface of each of the nozzles 221 to 228, and a gap is provided between the inner surface of each of the gas introduction ducts 211 to 218 and the outer surface of each of the nozzles 221 to 228. This allows a volume of a space between the gas introduction ducts 211 to 218 and the nozzles 221 to 228 to be reduced. Therefore, the retention of gas in the space is suppressed, thereby improving the efficiency of gas supply to the substrates. In addition, since a surface area in contact with gas is reduced, the generation of particles in the space may be suppressed. Thus, the space may be easily cleaned. In a cross-section perpendicular to a longitudinal direction of the nozzles 221 to 228, the inner surface of the gas introduction ducts 211 to 218 is, for example, circular, and the outer surface of the nozzles 221 to 228 is, for example, circular. In the cross-section perpendicular to the longitudinal direction of the nozzles 221 to 228, the inner surface of the gas introduction ducts 211 to 218 may be elliptical, and the outer surface of the nozzles 221 to 228 may also be elliptical.

The nozzles 221 to 228 are provided with gas discharge holes (not shown). The gas discharge holes are provided, for example, in portions of tube walls of the nozzles 221 to 228 inserted into the gas introduction ducts 211 to 218. Upper ends of the nozzles 221 to 228 are connected to gas sources (not shown) via the gas introduction pipes 231 to 238, respectively. Gases from the gas sources are introduced into the nozzles 221 to 228 from the upper ends of the nozzles 221 to 228 and discharged into the reaction tube 10 through the gas discharge holes, the gas holes 211a to 218a, and the introduction openings 10a. The nozzles 221 to 228 are not illustrated in FIGS. 2 to 5.

The nozzles 221 to 228 may not be provided. In this case, the upper ends of the gas introduction ducts 211 to 218 are connected to the gas sources via the gas introduction pipes 231 to 238, respectively. Gases from the gas sources are introduced into the gas introduction ducts 211 to 218 from the upper ends of the gas introduction ducts 211 to 218 and discharged into the reaction tube 10 through the gas holes 211a to 218a. For example, when gases that are easily thermally decomposed, such as hexachlorodisilane (HCD) gas and dichlorosilane (DCS) gas, are used, the nozzles 221 to 228 may not be necessary.

The gas introduction pipes 231 to 238 are installed in an upper space of the housing 50. One end of each of the gas introduction pipes 231 to 238 is connected to each of the corresponding gas introduction ducts 211 to 218 or the corresponding nozzles 221 to 228, and the other end of each of the gas introduction pipes 231 to 238 passes through the apparatus housing 90 and extends to an exterior of the apparatus housing 90. The gas introduction pipes 231 to 238 are provided with the opening/closing valves 241 to 248. The gas introduction pipes 231 to 238 may also be provided with flow rate controllers such as mass flow controllers.

The opening/closing valves 241 to 248 are installed in the upper space of the housing 50. The opening/closing valves 241 to 248 are installed in the middle of the corresponding gas introduction pipes 231 to 238. The opening/closing valves 241 to 248 are installed, for example, on an inner wall of the apparatus housing 90. The opening/closing valves 241 to 248 are valves that switch a gas flow on and off.

The vacuum pipe 30 has a cylindrical shape with an open lower end and a ceiling. The vacuum pipe 30 is installed spaced apart from the reaction tube 10. An opening 30a (FIG. 5) is formed on an outer wall of the vacuum pipe 30 at a same position as the exhaust duct 40 in a circumferential direction of the vacuum pipe 30. The opening 30a is a rectangular opening extending in the vertical direction from a vicinity of an upper end to a vicinity of a lower end of the vacuum pipe 30. A vertical length of the opening 30a may be the same as a vertical length of the exhaust opening 10b. An axis of the vacuum pipe 30 may be parallel to an axis of the reaction tube 10. The lower end of the vacuum pipe 30 is connected to an exhaust device (not shown) such as a vacuum pump via a pipe (not shown). A cross-sectional area of a flow path of the vacuum pipe 30 may be equal to or greater than a cross-sectional area of a flow path of the exhaust duct 40. In this case, exhaust flow velocity in the vertical direction becomes uniform, so that a uniform laminar flow in the vertical direction is formed. Thereby, inter-plane uniformity of the film formation or etching process is improved.

The exhaust duct 40 connects the reaction tube 10 and the vacuum pipe 30. The exhaust duct 40 allows communication between an interior of the reaction tube 10 and an interior of the vacuum pipe 30. One end of the exhaust duct 40 is connected to the outer wall of the reaction tube 10 to cover the exhaust opening 10b, and the other end of the exhaust duct 40 is connected to the outer wall of the vacuum pipe 30 to cover the opening 30a. In this case, compared to directly connecting the vacuum pipe 30 to the reaction tube 10 without providing the exhaust duct 40, a length X (FIG. 4) occupied by the exhaust duct 40 in the circumferential direction of the reaction tube 10 may be shortened. As a result, a length in which the gas introduction ducts 211 to 218 may be installed in the circumferential direction of the reaction tube 10 is lengthened. Thereby, the number of the gas introduction ducts 211 to 218 installed on the outer wall of the reaction tube 10 may be increased. The exhaust duct 40 may be divided into a plurality of parts in the vertical direction. In this case, a gas flow from the interior of the reaction tube 10 towards the vacuum pipe 30 is rectified. For this reason, the uniformity of the gas flow at different positions in the vertical direction inside the reaction tube 10 is improved.

The housing 50 accommodates the reaction tube 10, the gas introducer 20, the vacuum pipe 30, the exhaust duct 40, and the heating part 60 therein. Since the housing 50 accommodates the heating part 60 including a heater, the housing 50 is also called a heater shell. The housing 50 includes a bottom portion 51, a ceiling portion 52, and a side portion 53.

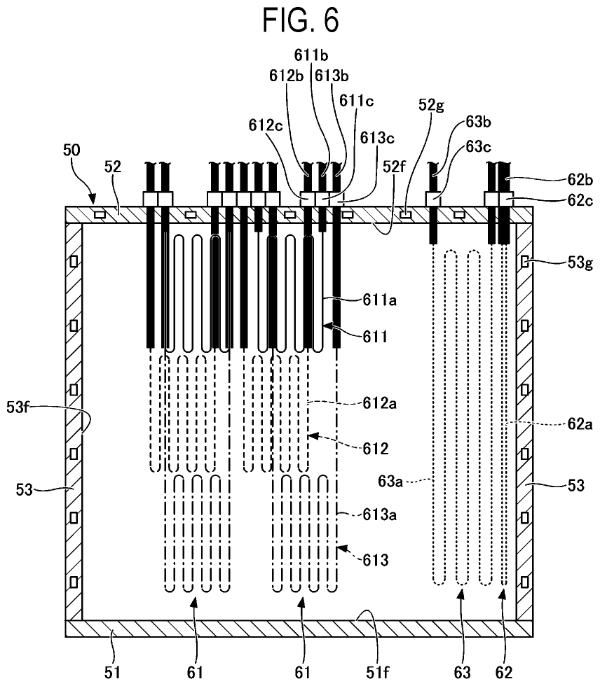

The bottom portion 51 supports the reaction tube 10 and the vacuum pipe 30. The bottom portion 51 is made of, for example, stainless steel. In this case, strength for supporting the reaction tube 10 and the vacuum pipe 30 is easily secured. The bottom portion 51 is, for example, a mirror-polished surface with a mirror-polished inner surface 51f (FIG. 6). In this case, it is easy to reflect thermal radiation.

The ceiling portion 52 is provided above the upper surface of the reaction tube 10 and an upper surface of the vacuum pipe 30. The ceiling portion 52 covers the upper surface of the reaction tube 10 and the upper surface of the vacuum pipe 30. The ceiling portion 52 is formed of, for example, stainless steel. In this case, high strength is obtained. The ceiling portion 52 is, for example, a mirror-polished surface with a mirror-polished inner surface 52f (FIG. 6). In this case, it is easy to reflect thermal radiation. The ceiling portion 52 may be formed of aluminum with the inner surface 52f which is a machined surface. Since the machined surface of aluminum easily reflects thermal radiation, a high reflectivity for thermal radiation is obtained without mirror-polishing the inner surface 52f. Therefore, the housing 50 may be manufactured at low cost. The ceiling portion 52 may be provided with a refrigerant flow path 52g (FIG. 6) for circulating a refrigerant. In this case, the ceiling portion 52 may be cooled by circulating the refrigerant through the refrigerant flow path 52g. In addition, since the upper surface of the reaction tube 10 is covered with the inner surface 52f of the cooled ceiling portion 52, temperature responsiveness during cooling of the reaction tube 10 may be enhanced even when the interior of the housing 50 is in a depressurized state.

The side portion 53 is provided around the reaction tube 10, the gas introducer 20, the vacuum pipe 30, and the exhaust duct 40. The side portion 53 covers the reaction tube 10, the gas introducer 20, the vacuum pipe 30, and the exhaust duct 40. A lower end of the side portion 53 is connected to the bottom portion 51, and an upper end of the side portion 53 is connected to the ceiling portion 52. The side portion 53 may be formed of, for example, aluminum with an inner surface 53f (FIG. 6) which is a machined surface. Since the machined surface of aluminum easily reflects thermal radiation, a high reflectivity for thermal radiation may be obtained without mirror-polishing the inner surface 53f. Therefore, the housing 50 may be manufactured at low cost. The side portion 53 may be provided with a refrigerant flow path 53g (FIG. 6) for circulating a refrigerant. In this case, the side portion 53 may be cooled by circulating the refrigerant through the refrigerant flow path 53g. In addition, since the side surface of the reaction tube 10 is covered with the cooled inner surface 53f, temperature responsiveness during cooling of the reaction tube 10 may be enhanced even when the interior of the housing 50 is in a depressurized state.

In this way, when the inner surfaces 51f, 52f, and 53f are the mirror-polished surfaces or machined surfaces, the thermal radiation from the heating part 60 may be reflected from the entire surfaces (the inner surfaces 51f, 52f, and 53f) of the housing 50 to uniformly heat the substrates.

The bottom portion 51, the ceiling portion 52, and the side portion 53 may be configured as separate bodies. The bottom portion 51, the ceiling portion 52, and the side portion 53 may be configured as a single body.

The heating part 60 is installed inside the housing 50. The heating part 60 includes a first side heater 61, a second side heater 62, a third side heater 63, a first ceiling heater 64, a second ceiling heater 65, and a lower heater 66. The first side heater 61, the second side heater 62, the third side heater 63, the first ceiling heaters 64, the second ceiling heaters 65, and the lower heater 66 are, for example, carbon wire heaters. In this case, the substrates accommodated inside the reaction tube 10 may be rapidly heated and cooled.

A plurality of first side heaters 61 is installed around the reaction tube 10. The plurality of first side heaters 61 is radially installed at intervals in the circumferential direction of the reaction tube 10. Each of the first side heaters 61 is positioned at a different location from the exhaust duct 40 in the circumferential direction of the reaction tube 10. Each of the first side heaters 61 may be divided into a plurality of parts in the vertical direction. In this case, temperature in the vertical direction may be independently adjusted by independently controlling the first side heaters 61 divided into the plurality of parts. As indicated by solid arrows in FIG. 4, the first side heaters 61 heat the substrates accommodated inside the reaction tube 10 from the exterior of the reaction tube 10 using thermal radiation.

The second side heater 62 is installed in a different position from the position of the first side heater 61 in the circumferential direction of the reaction tube 10. The second side heater 62 is installed in a different position from the positions of the plurality of gas introduction ducts 211 to 218 in the circumferential direction of the reaction tube 10. The second side heater 62 is installed in a position including a same position as the exhaust duct 40 in the circumferential direction of the reaction tube 10. Since the exhaust duct 40 is installed in a periphery of the reaction tube 10 at the same position as the exhaust duct 40 in the circumferential direction of the reaction tube 10, it is not possible to locate the second side heater 62. Therefore, the second side heater 62 is installed around the vacuum pipe 30. In other words, the second side heater 62 is installed at a position to which a distance from a center C1 of the reaction tube 10 is farther than a distance from the center C1 to the first side heater 61. For example, the second side heater 62, when viewed in a plane, is installed to include a virtual half straight line L extending through a center C3 of the vacuum pipe 30 starting from the center C1 of the reaction tube 10. The second side heater 62 may be divided into a plurality of parts in the vertical direction. In this case, temperature in the vertical direction may be independently adjusted by independently controlling the second side heater 62 divided into the plurality of parts. As indicated by a broken line arrow in FIG. 4, the second side heater 62 heats the vacuum pipe 30 and the exhaust duct 40 using thermal radiation and also heats the substrates accommodated inside the reaction tube 10. Thereby, the substrates accommodated inside the reaction tube 10 is heated from all directions around the reaction tube 10 by the first side heater 61 and the second side heater 62. Therefore, the in-plane temperature uniformity of a substrate is improved.

A plurality of third side heaters 63 is installed around the vacuum pipe 30. The plurality of third side heaters 63 is installed at intervals in the circumferential direction of the vacuum pipe 30. Each of the third side heaters 63 is positioned at a position different from the position of the second side heater 62 in the circumferential direction of the vacuum pipe 30. Each of the third side heaters 63, when viewed in a plane, is installed not to include the virtual half straight line L. Each third side heater 63 may be divided into a plurality of parts in the vertical direction. In this case, temperature in the vertical direction may be independently adjusted by independently controlling the third side heater 63 divided into the plurality of parts. As indicated by dash-dotted line arrows in FIG. 4, the third side heaters 63 heat the vacuum pipe 30.

The first ceiling heater 64 is installed between the upper surface of the reaction tube 10 and the ceiling portion 52 of the housing 50. The first ceiling heater 64 heats the substrates accommodated inside the reaction tube 10 from above the reaction tube 10 using thermal radiation. The number of first ceiling heaters 64 may be one or may be two or more.

The second ceiling heater 65 is installed between the upper surface of the vacuum pipe 30 and the ceiling portion 52 of the housing 50. The second ceiling heater 65 heats the vacuum pipe 30 from above the vacuum pipe 30 using thermal radiation. The number of second ceiling heaters 65 may be one or may be two or more.

A plurality of lower heaters 66 is installed in a periphery of a lower portion of the reaction tube 10. The plurality of the lower heaters 66 is installed radially at intervals in the circumferential direction of the reaction tube 10. The lower heaters 66 are positioned below the substrate holder 11. The lower heaters 66 heat the lower portion of the reaction tube 10 using thermal radiation and suppress heat dissipation from the lower end opening of the reaction tube 10.

The depressurizer 70 reduces pressure inside the housing 50. The depressurizer 70 includes a pipe 71, a safety valve 72, an opening/closing valve 73, and a vacuum pump 74.

The pipe 71 is connected to a port 53a installed in the side portion 53 of the housing 50. The pipe 71 penetrates through the side portion 53 and the apparatus housing 90 and extends to the exterior of the apparatus housing 90. In the pipe 71, the safety valve 72, the opening/closing valve 73, and the vacuum pump 74 are installed in this order from the housing 50. The safety valve 72, the opening/closing valve 73, and the vacuum pump 74 are installed, for example, outside the apparatus housing 90. The safety valve 72, the opening/closing valve 73, and the vacuum pump 74 may be installed outside the housing 50 and inside the apparatus housing 90.

When a pressure inside the housing 50 exceeds a set pressure, a state of the safety valve 72 is changed from a closed state to an open state, thereby maintaining the internal pressure of the housing 50 below the set pressure.

The opening/closing valve 73 is a valve that switches a gas flow on and off.

The vacuum pump 74 reduces the pressure inside the housing 50 through the pipe 71.

When the opening/closing valve 73 becomes an open state, the interior of the housing 50 is depressurized by the vacuum pump 74. In a state in which the interior of the housing 50 is depressurized, heat transfer by convection is suppressed. This suppresses heat transfer to the exterior of the housing 50, so that the space above the housing 50 may be used to install the opening/closing valves 241 to 248. In addition, since a thermal insulation material becomes unnecessary, a distance between the reaction tube 10 and the housing 50 may be shortened. Thereby, a distance from the opening/closing valves 241 to 248 to the substrates may be shortened and thus gas controllability is improved. Furthermore, when the side heaters (the first side heater 61, the second side heater 62, and the third side heater 63 are divided into a plurality of parts in the vertical direction, there is no influence of convection inside the housing 50, so that heaters have little influence on one another in the vertical direction. Therefore, inter-plane (vertical direction) temperature controllability is improved. This makes it easy to selectively heat only the lower portion of the reaction tube 10, selectively heat only the center of the reaction tube 10, or selectively heat only the upper portion of the reaction tube 10.

The pressurizer 80 restores the internal pressure of the depressurized housing 50 to atmospheric pressure. The pressurizer 80 includes a pipe 81, a gas source 82, a flow rate controller 83, and an opening/closing valve 84.

The pipe 81 is connected to a port 53b installed in the side portion 53 of the housing 50. In the pipe 81, the gas source 82, the flow rate controller 83, and the opening/closing valve 84 are installed in this order from an upstream to a downstream of a gas flow direction. The gas source 82, the flow rate controller 83, and the opening/closing valve 84 are installed, for example, outside the apparatus housing 90. The gas source 82, the flow rate controller 83, and the opening/closing valve 84 may be installed outside the housing 50 and inside the apparatus housing 90.

The gas source 82 is, for example, a supply source of an inert gas. The inert gas is, for example, nitrogen gas. The inert gas may be argon gas.

The flow rate controller 83 controls the flow rate of gas flowing through the pipe 81. The flow rate controller 83 is, for example, a mass flow controller.

The opening/closing valve 84 is a valve that switches a gas flow on and off.

When the opening/closing valve 84 becomes an open state, the flow rate of gas from the gas source 82 is controlled by the flow rate controller 83, and the gas with the controlled flow rate is supplied to the interior of the housing 50. Thereby, the internal pressure of the depressurized housing 50 is restored to atmospheric pressure.

The apparatus housing 90 surrounds the housing 50. The apparatus housing 90 covers

the entirety of the housing 50. The apparatus housing 90 supports the bottom portion 51 of the housing 50.

As described above, according to the substrate processing apparatus 1 of the embodiment, the reaction tube 10, the gas introducer 20, the vacuum pipe 30, and the exhaust duct 40 are accommodated inside the housing 50, and the heating part 60 is installed inside the housing 50. This allows the substrates accommodated inside the reaction tube 10 to be heated from all directions around the reaction tube 10. Thereby, the in-plane temperature uniformity of a substrate may be improved. As a result, processing uniformity of the substrate is improved.

### Side Heaters

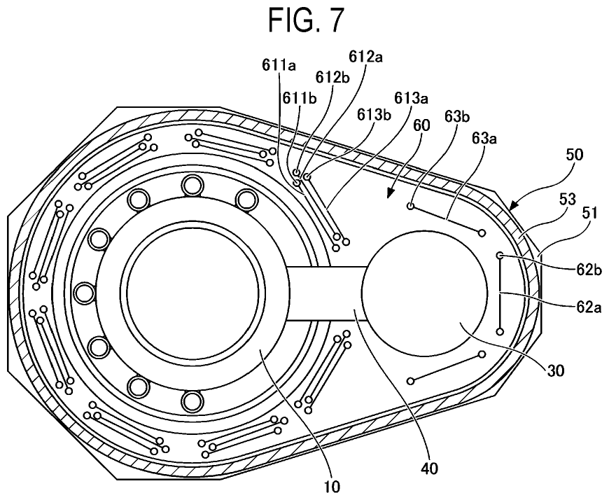

An example of side heaters (the first side heater 61, the second side heater 62, and the third side heater 63) will be described with reference to FIGS. 6 and 7. FIGS. 6 and 7 are views illustrating the arrangement of the side heaters. FIG. 6 is a vertical cross-sectional view, and FIG. 7 is a horizontal cross-sectional view. FIG. 7 shows a cross-section taken along line IV-IV in FIG. 3 in an arrow direction.

The first side heater 61 has an upper heater 611, a central heater 612, and a lower heater 613. The upper heater 611, the central heater 612, and the lower heater 613 are, for example, carbon wire heaters.

The upper heater 611 has a heater element 611a, a terminal 611b, and a sealing portion 611c. The heater element 611a is arranged at an upper portion within the housing 50. The heater element 611a has a configuration in which a high-purity carbon wire heating element is embedded within a quartz glass tube. The heater element 611a is formed, for example, in a wave-like shape in which a U-shape is continuously formed. The terminal 611b is connected to the heater element 611a and is drawn out above the housing 50 through the ceiling portion 52 in a sealed state by the sealing portion 611c. The upper heater 611 is supplied with power through the terminal 611b, so that the carbon wire heating element of the heater element 611a generates heat and heats the substrates arranged at the upper portion within the reaction tube 10.

The central heater 612 has a heater element 612a, a terminal 612b, and a sealing portion 612c. The heater element 612a is arranged at a central portion within the housing 50. The heater element 612a has a configuration in which a high-purity carbon wire heating element is embedded within a quartz glass tube. The heater element 612a is formed in, for example, a wave-like shape in which a U-shape is continuously formed. The terminal 612b is connected to the heater element 612a and is drawn out above the housing 50 through the ceiling portion 52 in a sealed state by the sealing portion 612c. The central heater 612 is supplied with power through the terminal 612b, so that the carbon wire heating element of the heater element 612a generates heat and heats the substrates arranged at the central portion within the reaction tube 10.

The lower heater 613 has a heater element 613a, a terminal 613b, and a sealing portion 613c. The heater element 613a is arranged at a lower portion within the housing 50. The heater element 613a has a configuration in which a high-purity carbon wire heating element is embedded within a quartz glass tube. The heater element 613a is formed, for example, in a wave-like shape in which a U shape is continuously formed. The terminal 613b is connected to the heater element 613a and is drawn out above the housing 50 through the ceiling portion 52 in a sealed state by the sealing portion 613c. The lower heater 613 is supplied with power through the terminal 613b, so that the carbon wire heating element of the heater element 613a generates heat and heats the substrates arranged at the lower portion within the reaction tube 10.

The terminal 611b of the upper heater 611, the terminal 612b of the central heater 612, and the terminal 613b of the lower heater 613 may be installed at positions offset from one another in a circumferential direction of the reaction tube 10, as shown in FIG. 7. In this case, while ensuring the maintainability of the terminals 611b, 612b, and 613b, the upper heater 611, the central heater 612, and the lower heater 613 may be brought close to the reaction tube 10. Therefore, the temperature controllability of the substrates accommodated inside the reaction tube 10 is improved. In addition, since the shapes of the heater elements 611a, 612a, and 613a may be made uniform, the manufacturing cost of the heater elements 611a, 612a, and 613a may be reduced.

The second side heater 62 has a heater element 62a, a terminal 62b, and a sealing portion 62c. The heater element 62a is arranged from the upper portion to the lower portion within the housing 50. The heater element 62a has a configuration in which a high-purity carbon wire heating element is embedded within a quartz glass tube. The heater element 62a is formed, for example, in a wave-like shape in which a U-shape is continuously formed. The terminal 62b is connected to the heater element 62a and is drawn out above the housing 50 through the ceiling portion 52 in a sealed state by the sealing portion 62c.

The third side heater 63 has a heater element 63a, a terminal 63b, and a sealing portion 63c. The heater element 63a is arranged from the upper portion to the lower portion within the housing 50. The heater element 63a has a configuration in which a high-purity carbon wire heating element is embedded within a quartz glass tube. The heater element 63a is formed, for example, in a wave-like shape in which a U-shape is continuously formed. The terminal 63b is connected to the heater element 63a and is drawn out above the housing 50 through the ceiling portion 52 in a sealed state by the sealing portion 63c.

As described above, all of the terminals 611b, 612b, 613b, 62b, and 63b of the side heaters (the upper heater 611, the central heater 612, the lower heater 613, the second side heater 62, and the third side heater 63) are drawn out above the housing 50 through the ceiling portion 52. As a result, maintenance work for all of the side heaters may be performed above the housing 50, making maintenance work easy.

For the first ceiling heater 64, the second ceiling heater 65, and the lower heater 66, terminals are drawn out above the housing through the ceiling portion 52 in the same manner as the terminals of the side heaters. As a result, maintenance work for the first ceiling heater 64, the second ceiling heater 65, and the lower heater 66 may be performed above the housing 50, making maintenance work easy. In addition, since the terminals of the heaters are not drawn out around the housing 50, the apparatus becomes compact.

In addition, in the above embodiment, the vacuum pipe 30 and the exhaust duct 40 are examples of a gas exhauster. The first side heater 61, the first ceiling heater 64, and the lower heater 66 are examples of a first heater. The second side heater 62, the third side heater 63, and the second ceiling heater 65 are examples of a second heater. The first side heater 61 is an example of a reaction tube side heater. The first ceiling heater 64 is an example of a reaction tube ceiling heater. The second side heater 62 and the third side heater 63 are examples of an exhaust side heater. The second ceiling heater 65 is an example of an exhaust ceiling heater. The upper heater 611, the center heater 612, and the lower heater 613 are examples of a plurality of split heaters.

It should be noted that the embodiments disclosed herein are exemplary in all aspects and are not restrictive. The above-described embodiments may be omitted, replaced, or modified in various forms without departing from the scope and spirit of the appended claims.

According to the present disclosure in some embodiments, it is possible to raise the in-plane temperature uniformity of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a reaction tube;
a gas introducer configured to introduce gas to an interior of the reaction tube;
a gas exhauster configured to exhaust the gas introduced to the interior of the reaction tube;
a first heater configured to heat the reaction tube;
a second heater configured to heat the gas exhauster; and
a housing configured to accommodate the reaction tube, the gas introducer, the gas exhauster, the first heater, and the second heater in an interior of the housing.

2. The substrate processing apparatus of claim 1, wherein the gas exhauster includes an exhaust duct formed integrally with the reaction tube and a vacuum pipe connected to the reaction tube via the exhaust duct, and
wherein an axis of the vacuum pipe is parallel to an axis of the reaction tube.

3. The substrate processing apparatus of claim 2, wherein the housing includes a side portion installed around the reaction tube and the vacuum pipe,
wherein the side portion is formed of aluminum, and
wherein an inner surface of the side portion is a machined surface.

4. The substrate processing apparatus of claim 3, wherein a refrigerant flow path is formed in the side portion.

5. The substrate processing apparatus of claim 4, wherein the housing further includes a ceiling portion configured to cover an upper surface of the reaction tube and an upper surface of the vacuum pipe,
wherein the first heater comprises:
a first heater element installed inside the housing; and
a first terminal connected to the first heater element and drawn out above the housing through the ceiling portion, and
wherein the second heater comprises:
a second heater element installed inside the housing; and
a second terminal connected to the second heater element and drawn out above the housing through the ceiling portion.

6. The substrate processing apparatus of claim 4, wherein the first heater and the second heater are carbon wire heaters.

7. The substrate processing apparatus of claim 4, wherein the first heater comprises:
a reaction tube side heater configured to heat the reaction tube from around the reaction tube; and
a reaction tube ceiling heater configured to heat the reaction tube from above the reaction tube, and
wherein the second heater comprises:
an exhaust side heater configured to heat the vacuum pipe from around the vacuum pipe; and
an exhaust ceiling heater configured to heat the vacuum pipe from above the vacuum pipe.

8. The substrate processing apparatus of claim 7, wherein the reaction tube side heater includes a plurality of split heaters divided in a vertical direction, and
wherein terminals of the plurality of split heaters are installed at positions offset from one another in a circumferential direction of the reaction tube.

9. The substrate processing apparatus of claim 2, wherein the housing includes a ceiling portion configured to cover an upper surface of the reaction tube and an upper surface of the vacuum pipe,
wherein the first heater comprises:
a first heater element installed inside the housing; and
a first terminal connected to the first heater element and drawn out above the housing through the ceiling portion, and
wherein the second heater comprises:
a second heater element installed inside the housing; and
a second terminal connected to the second heater element and drawn out above the housing through the ceiling portion.

10. The substrate processing apparatus of claim 2, wherein the first heater and the second heater are carbon wire heaters.

11. The substrate processing apparatus of claim 2, wherein the first heater comprises:
a reaction tube side heater configured to heat the reaction tube from around the reaction tube; and
a reaction tube ceiling heater configured to heat the reaction tube from above the reaction tube, and
wherein the second heater includes:
an exhaust side heater configured to heat the vacuum pipe from around the vacuum pipe; and
an exhaust ceiling heater configured to heat the vacuum pipe from above the vacuum pipe.

12. The substrate processing apparatus of claim 1, further comprising a depressurizer configured to depressurize the interior of the housing.
